(19) United States
(12) Patent Application Publication
(10) Pub. No.: US 2024/0055489 A1
(43) Pub. Date: Feb. 15, 2024

(54) HOMOGENIZATION FIELD DEVICE WITH LOW SPECIFIC ON-RESISTANCE BASED ON MULTIDIMENSIONAL COUPLED VOLTAGE DIVIDING MECHANISM AND ITS MANUFACTURING METHOD

(71) Applicant: University of Electronic Science and Technology of China, Chengdu (CN)

(72) Inventors: Bo ZHANG, Chengdu (CN); Lingying WU, Chengdu (CN); Yuting LIU, Chengdu (CN); Wentong ZHANG, Chengdu (CN); Zhaoji LI, Chengdu (CN)

(73) Assignee: University of Electronic Science and Technology of China, Chengdu (CN)

(21) Appl. No.: 17/994,027

(22) Filed: Nov. 25, 2022

(30) Foreign Application Priority Data
Aug. 10, 2022 (CN) 202210600368.6

(51) Int. Cl. H01L 29/40; H01L 29/423

(52) U.S. Cl. CPC H01L 29/407; H01L 29/404; H01L 29/4238

(57) ABSTRACT

A homogenization field device with low specific on-resistance based on multidimensional coupled voltage dividing mechanism includes a first conductive type semiconductor substrate, a first conductive type well region, a first conductive type semiconductor contact region, a second conductive type drift region, a second conductive type well region, a second conductive type semiconductor contact region, a first dielectric oxide layer, a second dielectric oxide layer, a third dielectric oxide layer, a fourth dielectric oxide layer, a polycrystalline silicon electrode of a floating field plate, a polycrystalline silicon electrode of a control gate, a first layer of metal strips and a second layer of metal strips. The first dielectric oxide layer and the polycrystalline silicon electrode of the floating field plate form a vertical floating field plate, and the first layer of metal strips, the second layer of metal strips and the fourth dielectric oxide layer form a surface fixed dielectric capacitor.

### CROSS REFERENCE TO THE RELATED APPLICATIONS

This application is based upon and claims priority to Chinese Patent Application No. 202210600368.6, filed on Aug. 10, 2022, the entire contents of which are incorporated herein by reference.

### TECHNICAL FIELD

The present invention belongs to the technical field of power semiconductors and mainly provides a homogenization field device with low specific on-resistance based on multidimensional coupled voltage dividing mechanism and its manufacturing method.

### BACKGROUND

Power semiconductor devices have high input impedance, low loss, high switching speed, wide safe operating area and thus have been widely applied to many aspects such as consumer electronics, computers and peripheral equipment, network communication, dedicated electronic equipment and instruments and apparatus, automotive electronics, LED display screens and electronic lighting. Lateral devices are widely used in power integrated circuits because the source, gate, and drain are on the surfaces of chips and are easily integrated with other devices and circuits through internal connections. In design of the lateral devices, it is required that the devices have high breakdown voltages and low specific on-resistance. For the high breakdown voltages, the devices need to have long drift regions and low doping concentrations of the drift regions, which also causes increased specific on-resistance of the devices.

In order to relieve a contradictory relation between the breakdown voltage and the specific on-resistance, some researchers have provided a device with vertical floating field plates and its manufacturing method (CN201910819933.6). This invention improves the breakdown voltage of the device by introducing a full-depletion MIS mechanism in a case where the device is in an off state. Meanwhile, in a case where the device is in the off state, an accumulation layer can be formed on the surface of the floating field plates, so that the specific on-resistance is reduced and the saturation current is improved. In a case where the device is in the off state, since the breakdown voltage is subjected to coupled voltage division of a variable capacitor of an internal semiconductor, the device is depleted discontinuously, and the voltage is divided non-uniformly, so that further improvement of the breakdown voltage of the device is limited. The present invention provides a homogenization field a Homogenization field device with low specific on-resistance based on multidimensional coupled voltage dividing mechanism and its manufacturing method. The present invention replaces a coupled voltage dividing mode of the variable capacitor of the internal semiconductor with a coupled voltage dividing mode of the surface fixed dielectric capacitor, which solves the problems that the device is depleted discontinuously and the voltage is divided non-uniformly, so that the device has a higher breakdown voltage. The manufacturing method is relatively simple.

### SUMMARY

Aiming at the problems in the background technology, by introducing the multidimensional coupled voltage division mechanism to the surface of the device, the present invention provides a homogenization field device with low specific on-resistance based on multidimensional coupled voltage dividing mechanism, so that the breakdown voltage of the device can be further improved, and the specific on-resistance can be reduced.

In order to achieve the above invention purpose, the present invention adopts a technical solution as follows:

A homogenization field device with low specific on-resistance based on multidimensional coupled voltage dividing mechanism, includes:

A first conductive type semiconductor substrate, a first conductive type well region, a first conductive type source heavily doped region, a second conductive type drift region, a second conductive type well region, a second conductive type source heavily doped region, a second conductive type drain heavily doped region, a first dielectric oxide layer, a second dielectric oxide layer, a third dielectric oxide layer, a fourth dielectric oxide layer, a polycrystalline silicon electrode, a polycrystalline silicon electrode of a control gate, a first layer of metal strips, a second layer of metal strips, a source electrode metal and a drain electrode metal, where the second conductive type drift region is located above the first conductive type semiconductor substrate, the first conductive type well region is located on the left side of the second conductive type drift region, the second conductive type well region is located on the right side of the second conductive type drift region, the first conductive type source heavily doped region and the second conductive type source heavily doped region on a source side region are located in the first conductive type well region and both are heavily doped to reduce resistance, and the source electrode metal is located on upper surfaces of the first conductive type source heavily doped region and the second conductive type source heavily doped region; the second conductive type drain heavily doped region is located in the second conductive type well region, and the drain electrode metal is located on an upper surface of the second conductive type drain heavily doped region; the second dielectric oxide layer is located above the first conductive type well region, and a left end of the second dielectric oxide layer contacts the second conductive type source heavily doped region and a right end thereof contacts the second conductive type drift region; the third dielectric oxide layer is located on an upper surface of the second conductive type drift region located between the second dielectric oxide layer and the second conductive type drain heavily doped region, and the fourth dielectric oxide layer is located on a surface of the device; the polycrystalline silicon electrode of the control gate covers an upper surface of the second dielectric oxide layer and partially extends to an upper surface of the third dielectric oxide layer; the first layer of metal strips are located on the upper surface of the third dielectric oxide layer and in the fourth dielectric oxide layer, the second layer of metal strips are located on an upper surface of the fourth dielectric oxide layer, and a heavy doping concentration is greater than 1E18 cm⁻³;

The first dielectric oxide layer and the polycrystalline silicon electrode form a vertical floating field plate, and the first dielectric oxide layer encircles the polycrystalline silicon electrode, the vertical floating field plates are distributed in the entire second conductive type drift region to form a vertical floating field plate array, the vertical floating field plates separated from a source electrode and a drain electrode at an equal interval and distributed in the entire second conductive type drift region are connected to the first layer of metal strips via holes; a fixed capacitor formed between the first layer of metal strips distributed at an equal interval on the upper surface of the third dielectric oxide layer and in the fourth dielectric oxide layer and the second layer of metal strips distributed at an equal interval on the upper surface of the fourth dielectric oxide layer enables a potential of the vertical floating field plate array distributed in the entire second conductive type drift region to be fixed through a capacitive coupling effect in a case that the device is in an off state, so that the second conductive type drift region is depleted continuously and the voltage is divided uniformly;

The second layer of metal strips and the first layer of metal strips realize multidimensional coupled voltage division; a direction from the source electrode to the drain electrode is an x direction, a depth downward direction of each of the vertical floating field plates is a y direction, and a z direction is perpendicular to the x direction and the y direction.

As a preferred mode, the second layer of metal strips are continuous vertical strips in the z direction that are repeatedly arranged along the x direction or discrete vertical strips in the z direction that are repeatedly arranged along the x direction or the continuous vertical strips in the z direction and the discrete vertical strips in the z direction that are alternately arranged.

As a preferred mode, the first layer of metal strips is made from a polycrystalline silicon material, the second layer of metal strips and the first layer of metal strips are connected via holes and are staggered in the x direction, or a plurality of layers of metal strips and the first layer of metal strips are connected via holes and are staggered in the x direction to realize multidimensional coupled voltage division.

As a preferred mode, a drain vertical floating field plate is formed at drain region by using a process identical to the vertical floating field plate array in the second conductive type drift region, the drain vertical floating field plate penetrates through the second conductive type drain heavily doped region and the second conductive type well region, and a polycrystalline silicon electrode of the drain vertical floating field plate is connected to the drain electrode metal.

As a preferred mode, the vertical floating field plates form an internal parallel equipotential ring array or an internal staggered equipotential ring array.

As a preferred mode, a first conductive type buried layer is introduced into the second conductive type drift region.

As a preferred mode, a first conductive type top layer is introduced onto the surface of the second conductive type drift region.

As a preferred mode, a layer of dielectric layer is sandwiched between top layer silicon and a first conductive type semiconductor substrate.

The present invention further provides method for manufacturing a homogenization field device with low specific on-resistance based on multidimensional coupled voltage dividing mechanism, including the following steps:
S1: selecting a first conductive type semiconductor;
S2: performing ion implantation of a second conductive type impurity and performing heating process promotion to form a second conductive type drift region;
S3: forming a trench by Photolithography and etching;
S4: forming a first dielectric oxide in the trench;
S5: depositing polycrystal silicon and etching the polycrystal silicon to a silicon plane to form a polycrystalline silicon electrode;
S6: performing ion implantation of the first conductive type impurity and high temperature diffusion process to form junction to form a first conductive type well region, and then performing ion implantation of the second conductive type impurity and high temperature diffusion process to form junction to form a second conductive type well region;
S7: forming a second dielectric oxide layer and then forming a third dielectric oxide layer;
S8: depositing the polycrystal silicon and etching the polycrystal silicon to form a polycrystalline silicon electrode of the control gate;
S9: performing ion implantation to form a first conductive type source heavily doped region, a second conductive type source heavily doped region and a second conductive type drain heavily doped region;
S10: etching the third dielectric oxide layer to form a contact hole, and then depositing and etching to form a first layer of metal strips, or depositing and etching to form a first layer of polycrystalline silicon strips;
S11: depositing to form a fourth dielectric oxide layer;
S12: depositing and etching to form a second layer of metal strips, a source electrode metal and a drain electrode metal.

As a preferred mode, the second conductive type drift region formed by implantation and high temperature diffusion process to form junction in S2 is obtained by an epitaxial method; and/or the first conductive type well region and the second conductive type well region obtained by implantation and high temperature diffusion process to form junction in S6 are formed by multiple implantations of different energies and activated.

The present invention has the beneficial effects that by introducing the multidimensional coupled voltage division mechanism onto the surface of the device, the present invention replaces the coupled voltage dividing mode of the variable capacitor of the internal semiconductor with the coupled voltage dividing mode of the surface fixed dielectric capacitor, which solves the problems that the device is depleted discontinuously and the voltage is divided non-uniformly, so that the device has a higher breakdown voltage.

### BRIEF DESCRIPTION OF THE DRAWINGS

FIG. 1 is a planar structural diagram of a homogenization field device with low specific on-resistance based on multidimensional coupled voltage dividing mechanism in an embodiment 1.

FIG. 2 is a stereo schematic structural diagram of a homogenization field device with low specific on-resistance based on multidimensional coupled voltage dividing mechanism in an embodiment 2.

FIG. 3 is a stereo schematic structural diagram of a homogenization field device with low specific on-resistance based on multidimensional coupled voltage dividing mechanism in an embodiment 3.

FIG. 4 is a stereo schematic structural diagram of a homogenization field device with low specific on-resistance based on multidimensional coupled voltage dividing mechanism in an embodiment 4.

FIG. 5 is a stereo schematic structural diagram of a homogenization field device with low specific on-resistance based on multidimensional coupled voltage dividing mechanism in an embodiment 5.

FIG. 6 is a planar structural diagram of a homogenization field device with low specific on-resistance based on multidimensional coupled voltage dividing mechanism in an embodiment 5.

FIG. 7 is a planar structural diagram of a homogenization field device with low specific on-resistance based on multidimensional coupled voltage dividing mechanism in an embodiment 6.

FIG. 8 is a stereo schematic structural diagram of a homogenization field device with low specific on-resistance based on multidimensional coupled voltage dividing mechanism in an embodiment 7.

FIG. 9 is a stereo schematic structural diagram of a homogenization field device with low specific on-resistance based on multidimensional coupled voltage dividing mechanism in an embodiment 8.

FIG. 10 is a structural top view of a homogenization field device with low specific on-resistance based on multidimensional coupled voltage dividing mechanism in an embodiment 8.

FIG. 11 is a stereo schematic structural diagram of a homogenization field device with low specific on-resistance based on multidimensional coupled voltage dividing mechanism in an embodiment 9.

FIG. 12 is a structural top view of a homogenization field device with low specific on-resistance based on multidimensional coupled voltage dividing mechanism in an embodiment 9.

FIG. 13 is a stereo schematic structural diagram of a homogenization field device with low specific on-resistance based on multidimensional coupled voltage dividing mechanism in an embodiment 10.

FIG. 14 is a stereo schematic structural diagram of a homogenization field device with low specific on-resistance based on multidimensional coupled voltage dividing mechanism in an embodiment 11.

FIG. 15 is a stereo schematic structural diagram of a homogenization field device with low specific on-resistance based on multidimensional coupled voltage dividing mechanism in an embodiment 12.

FIG. 16A to FIG. 16L are schematic diagrams of a process flow of the device in the embodiment 1.

11—first conductive type semiconductor substrate; 12—first conductive type well region; 13—first conductive type source heavily doped region; 21—second conductive type drift region; 22—second conductive type well region; 23—second conductive type source heavily doped region; 24—second conductive type drain heavily doped region; 31—first dielectric oxide layer; 32—second dielectric oxide layer; 33—third dielectric oxide layer; 34—fourth dielectric oxide layer; 41—polycrystalline silicon electrode; 42—polycrystalline silicon electrode of control gate; 51—first layer of metal strips; 52—second layer of metal strips; 53—source electrode metal; 54—drain electrode metal.

### DETAILED DESCRIPTION OF THE EMBODIMENTS

Implementation modes of the present invention are described below through specific examples. Those skilled in the art can easily understand other advantages and functions of the present invention from the content disclosed by the description. The present invention can further be implemented or applied through other different specific implementation modes. Details in the descriptions can be based on different perspectives and applications, and various modifications or variations can be made without departing from the spirit of the present invention.

### Embodiment 1

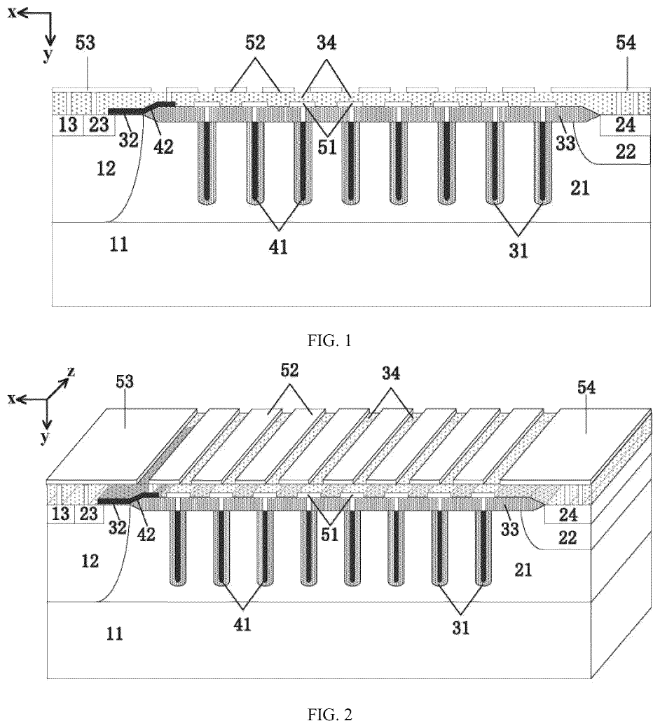

A homogenization field device with low specific on-resistance based on multidimensional coupled voltage dividing mechanism in an embodiment 1, as shown in FIG. 1, includes:

A first conductive type semiconductor substrate 11, a first conductive type well region 12, a first conductive type source heavily doped region 13, a second conductive type drift region 21, a second conductive type well region 22, a second conductive type source heavily doped region 23, a second conductive type drain heavily doped region 24, a first dielectric oxide layer 31, a second dielectric oxide layer 32, a third dielectric oxide layer 33, a fourth dielectric oxide layer 34, a polycrystalline silicon electrode 41, a polycrystalline silicon electrode 42 of a control gate, a first layer of metal strips 51, a second layer of metal strips 52, a source electrode metal 53 and a drain electrode metal 54, where the second conductive type drift region 21 is located above the first conductive type semiconductor substrate 11, the first conductive type well region 12 is located on the left side of the second conductive type drift region 21, the second conductive type well region 22 is located on the right side of the second conductive type drift region 21, the first conductive type source heavily doped region 13 and the second conductive type source heavily doped region 23 on a source side region are located in the first conductive type well region 12 and both are heavily doped to reduce resistance, and the source electrode metal 53 is located on upper surfaces of the first conductive type source heavily doped region 13 and the second conductive type source heavily doped region 23; the second conductive type drain heavily doped region 24 is located in the second conductive type well region 22, and the drain electrode metal 54 is located on an upper surface of the second conductive type drain heavily doped region 24; the second dielectric oxide layer 32 is located above the first conductive type well region 12, and a left end of the second dielectric oxide layer contacts the second conductive type source heavily doped region 23 and a right end thereof contacts the second conductive type drift region 21; the third dielectric oxide layer 33 is located on an upper surface of the second conductive type drift region 21 located between the second dielectric oxide layer 32 and the second conductive type drain heavily doped region 24, and the fourth dielectric oxide layer 34 is located on a surface of the device; the polycrystalline silicon electrode 42 of the control gate covers an upper surface of the second dielectric oxide layer 32 and partially extends to an upper surface of the third dielectric oxide layer 33; the first layer of metal strips 51 are located on the upper surface of the third dielectric oxide layer 33 and in the fourth dielectric oxide layer 34, the second layer of metal strips 52 are located on an upper surface of the fourth dielectric oxide layer 34, and a heavy doping concentration is greater than 1E18 cm⁻³;

The first dielectric oxide layer 31 and the polycrystalline silicon electrode 41 form a vertical floating field plate, and the first dielectric oxide layer 31 encircles the polycrystalline silicon electrode 41, the vertical floating field plates are distributed in the entire second conductive type drift region 21 to form a vertical floating field plate array, the vertical floating field plates separated from a source electrode and a drain electrode at an equal interval and distributed in the entire second conductive type drift region 21 are connected to the first layer of metal strips 51 via holes; a fixed capacitor formed between the first layer of metal strips 51 distributed at an equal interval on the upper surface of the third dielectric oxide layer 33 and in the fourth dielectric oxide layer 34 and the second layer of metal strips 52 distributed at an equal interval on the upper surface of the fourth dielectric oxide layer 34 enables a potential of the vertical floating field plate array distributed in the entire second conductive type drift region 21 to be fixed through a capacitive coupling effect in a case that the device is in an off state, so that the second conductive type drift region 21 is depleted continuously and the voltage is divided uniformly;

The second layer of metal strips 52 and the first layer of metal strips 51 realize multidimensional coupled voltage division; a direction from the source electrode to the drain electrode is an x direction, a depth downward direction of each of the vertical floating field plates is a y direction, and a z direction is perpendicular to the x direction and the y direction.

The working mechanism of the device is as follows:

Taking the first conductive type semiconductor material being P type as an example, in a case where a bias voltage Vg of the gate electrode is 0, a universal MIS depletion mechanism is introduced into the vertical floating field plate. An MIS structure itself has charge balance, and the drift region 21 of the device can be depleted independent from the substrate. Since the breakdown voltage is subjected to coupled voltage division of a variable capacitor of an internal semiconductor, the device is depleted discontinuously, and the voltage is divided non-uniformly, so that further improvement of the breakdown voltage of the device is limited. By introducing a multidimensional coupled voltage division mechanism onto the surface of the device, the present invention replaces the coupled voltage dividing mode of the variable capacitor of the internal semiconductor with the coupled voltage dividing mode of the surface fixed dielectric capacitor, which solves the problems that the device is depleted discontinuously and the voltage is divided non-uniformly, so that the device has a higher breakdown voltage. Therefore, the concentration of the second conductive type drift region 21 can be increased, and the specific on-resistance can be reduced. In a case where the bias voltage Vg of the gate electrode is greater than a threshold voltage, inversion layer electrons appear on the surface of the first conductive type well region 12 close to the second dielectric oxide layer 32. Under the effect of a bias voltage Vd at the drain, the electrons move from the source to the drain along a gap of the floating field plate. In conclusion, the technique proposed by the present invention optimizes the internal electric field of the device, and the device has the higher breakdown voltage compared with that of a conventional device.

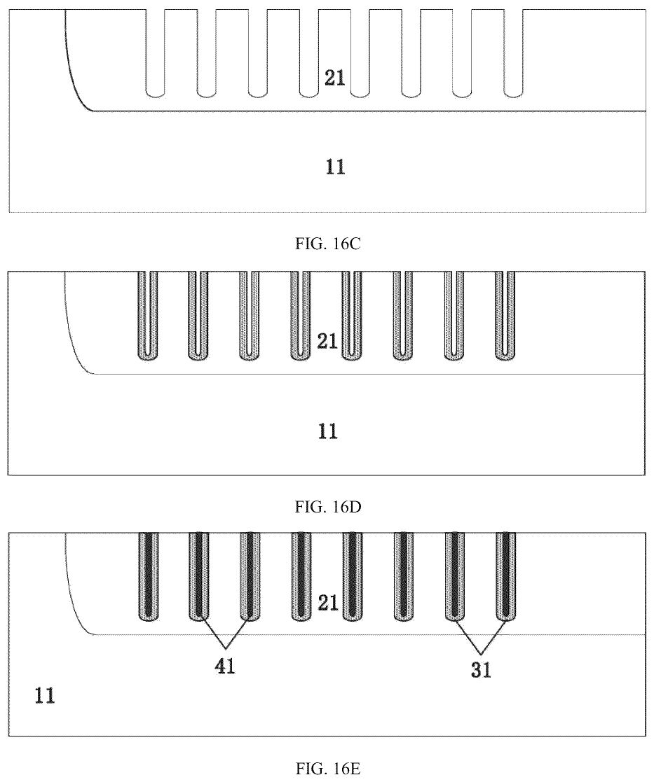

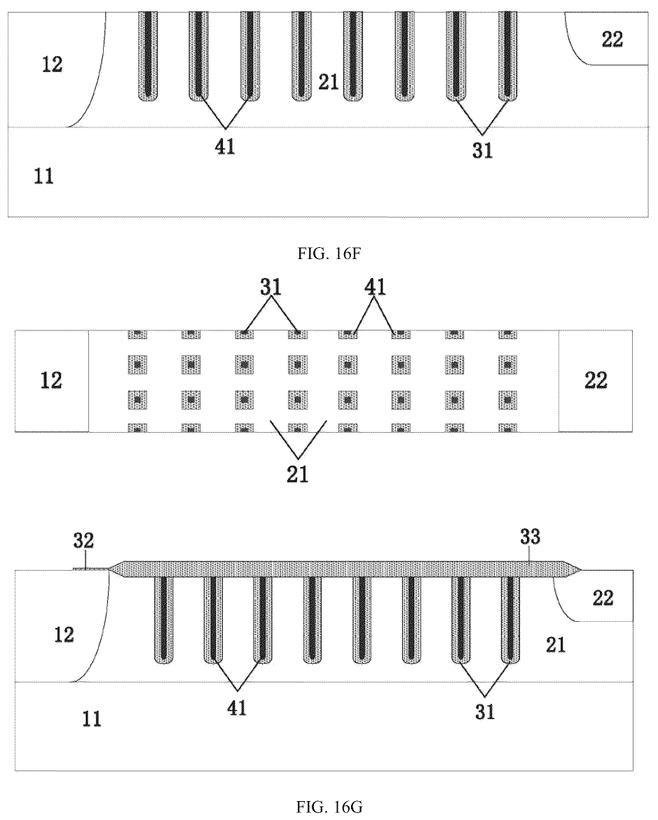

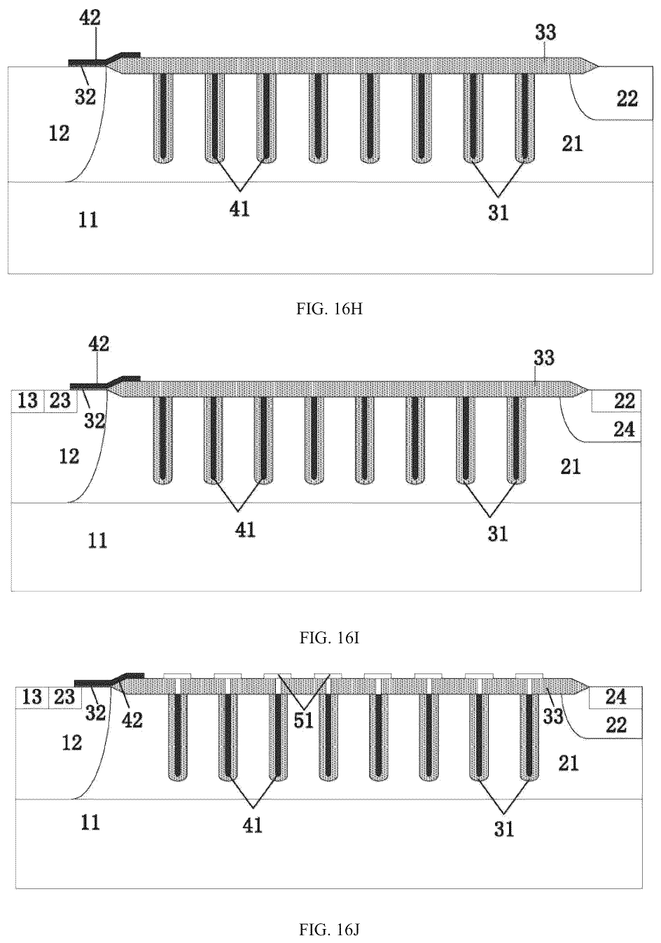

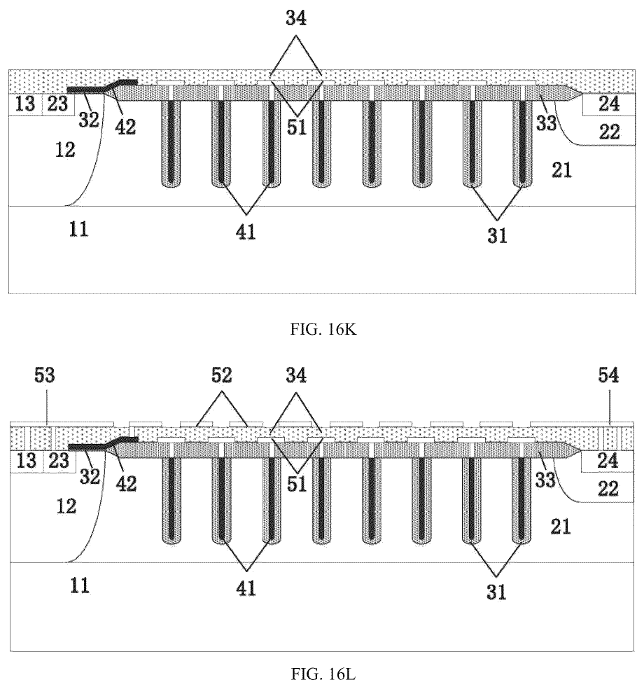

As shown in FIGS. 16A-16L, FIGS. 16A-16L are schematic diagrams of a process flow in the embodiment 1 of the present invention, specifically including the following steps:
S1: a first conductive type semiconductor 11 is selected, as shown in FIG. 16A;
S2: ion implantation of a second conductive type impurity is performed and heating process promotion is performed to form a second conductive type drift region 21, as shown in FIG. 16B;
S3: a trench is formed by Photolithography and etching, as shown in FIG. 16C;
S4: a first dielectric oxide 31 is formed in the trench, as shown in FIG. 16D;
S5: polycrystal silicon is deposited and the polycrystal silicon is etched to a silicon plane to form a polycrystalline silicon electrode 41, as shown in FIG. 16E;
S6: ion implantation of the first conductive type impurity is performed and high temperature diffusion process to form junction is performed to form a first conductive type well region 12, and then ion implantation of the second conductive type impurity and high temperature diffusion process to form junction are performed to form a second conductive type well region 22, as shown in FIG. 16F;
S7: a second dielectric oxide layer 32 is formed and then a third dielectric oxide layer 33 is formed, as shown in FIG. 16G;
S8: the polycrystal silicon is deposited and the polycrystal silicon is etched to form a polycrystalline silicon electrode 42 of the control gate, as shown in FIG. 16H;
S9: ion implantation is performed to form a first conductive type source heavily doped region 13, a second conductive type source heavily doped region 23 and a second conductive type drain heavily doped region 24, as shown in FIG. 16I;
S10: the third dielectric oxide layer 33 is etched form to a contact hole, and then a first layer of metal strips 51 are deposited and etched, or a first layer of polycrystalline silicon strips is deposited and etched to form a surface metal strip, as shown in FIG. 16J;
S11: a fourth dielectric oxide layer 34 are deposited and formed, as shown in FIG. 16K;
S12: a second layer of metal strips 52, a source electrode metal 53 and a drain electrode metal 54 are deposited and etched, as shown in FIG. 16L.

It is to be noted that

according to the manufacturing method, the second conductive type drift region 21 formed by high energy implantation and high temperature diffusion process to form junction in S2 can be further obtained by an epitaxial method;

According to the manufacturing method, the first conductive type well region 12 and the second conductive type well region 22 obtained by implantation and high temperature diffusion process to form junction in S6 can be further formed by multiple implantations of different energies and activated.

### Embodiment 2

As shown in FIG. 2, FIG. 2 is a schematic structural diagram of a homogenization field device with low specific on-resistance based on multidimensional coupled voltage dividing mechanism in the embodiment 2. The difference between the embodiment and the embodiment 1 lies in that the second layer of metal strips 52 is continuous vertical strips in the z direction that are repeatedly arranged along the x direction, and its working mechanism is substantially same with that of the embodiment 1.

### Embodiment 3

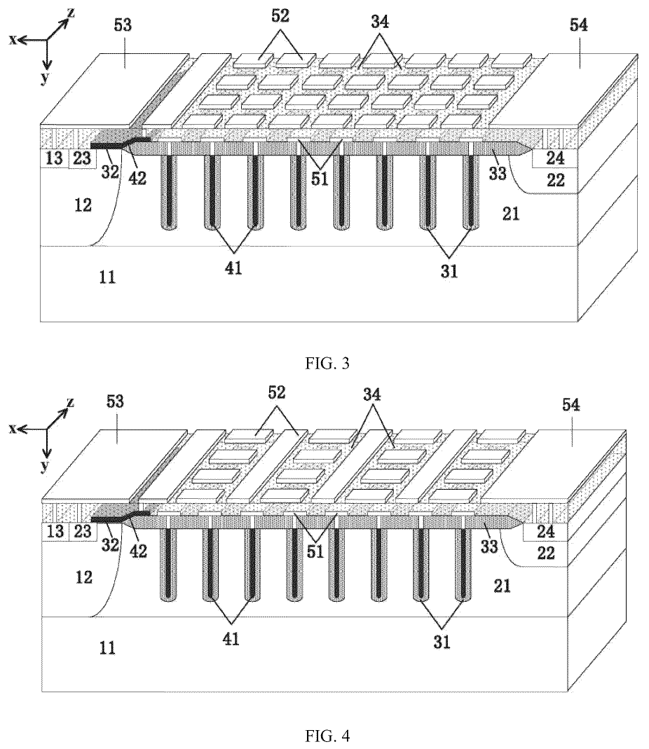

As shown in FIG. 3, FIG. 3 is a schematic structural diagram of a homogenization field device with low specific on-resistance based on multidimensional coupled voltage dividing mechanism in the embodiment 3. The difference between the embodiment 3 and the embodiment 1 lies in that the second layer of metal strips 52 is discrete vertical strips in the z direction that are repeatedly arranged along the x direction. Its working mechanism is substantially same with that of the embodiment 1.

### Embodiment 4

As shown in FIG. 4, FIG. 4 is a schematic structural diagram of a homogenization field device with low specific on-resistance based on multidimensional coupled voltage dividing mechanism in the embodiment 4. The difference between the embodiment 4 and the embodiment 1 lies in that the second layer of metal strips 52 is the continuous vertical strips in the z direction and the discrete vertical strips in the z direction that are alternately arranged along the x direction, and its working mechanism is substantially same with that of the embodiment 1.

### Embodiment 5

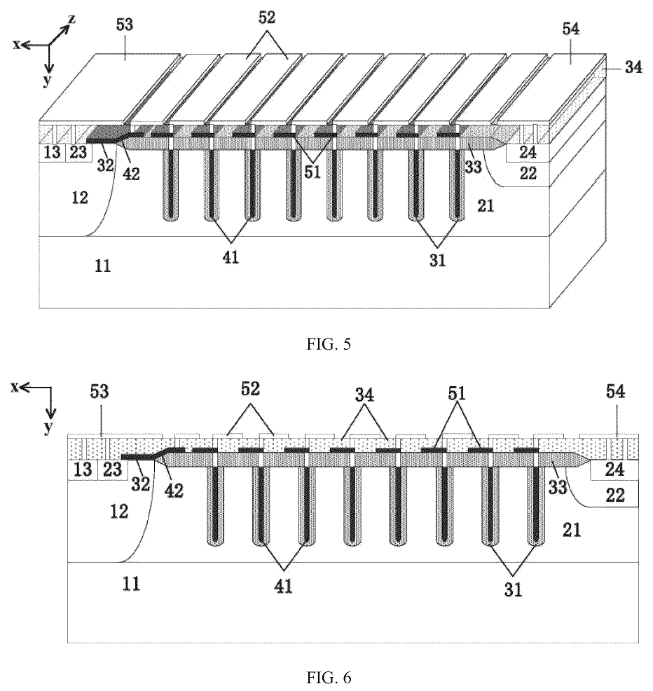

As shown in FIG. 5 and FIG. 6, FIG. 5 and FIG. 6 are schematic structural diagrams of a homogenization field device with low specific on-resistance based on multidimensional coupled voltage dividing mechanism in the embodiment 5. The difference between the embodiment 5 and the embodiment 1 lies in that the second layer of metal strips 52 and the first layer of metal strips 51 are connected via holes and are staggered in the x direction, and its working mechanism is substantially same with that of the embodiment 1.

### Embodiment 6

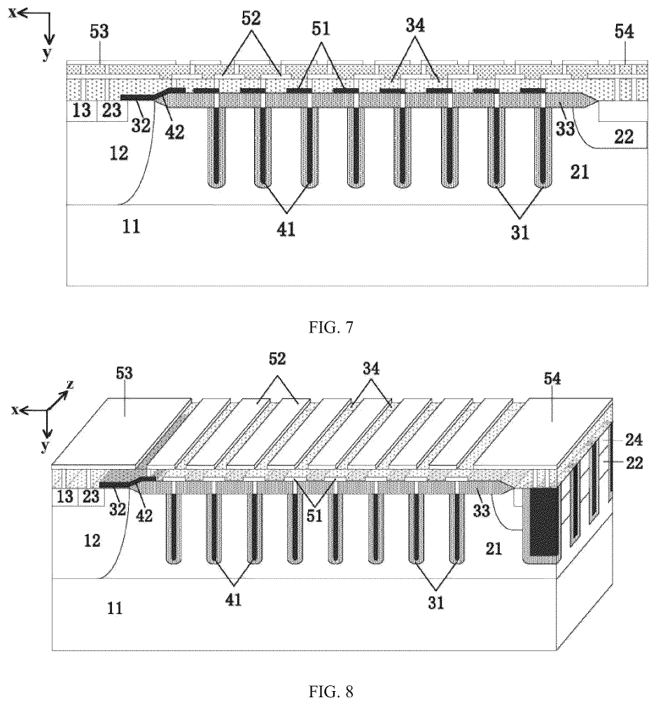

As shown in FIG. 7, FIG. 7 is a schematic structural diagram of a homogenization field device with low specific on-resistance based on multidimensional coupled voltage dividing mechanism in the embodiment 6. The difference between the embodiment 6 and the embodiment 5 lies in that the plurality of layers of metal strips and the first layer of metal strips 51 are connected via holes and are staggered in the x direction to realize multidimensional coupled voltage division.

### Embodiment 7

As shown in FIG. 8, FIG. 8 is a schematic structural diagram of a homogenization field device with low specific on-resistance based on multidimensional coupled voltage dividing mechanism in the embodiment 7. The difference between the embodiment 7 and the embodiment 1 lies in that the drain vertical field plate is formed at the drain by using a process same with that of the vertical floating field plate in the second conductive type drift region 21, the vertical floating field plate in the drift region and the drain vertical field plate are inserted into the substrate, the vertical floating field plate can deplete the first conductive type semiconductor substrate 11 and the second conductive type drift region 21 simultaneously and the drain vertical field plate optimizes the internal electric field at the drain, and its working mechanism is substantially same with that of the embodiment 1.

### Embodiment 8

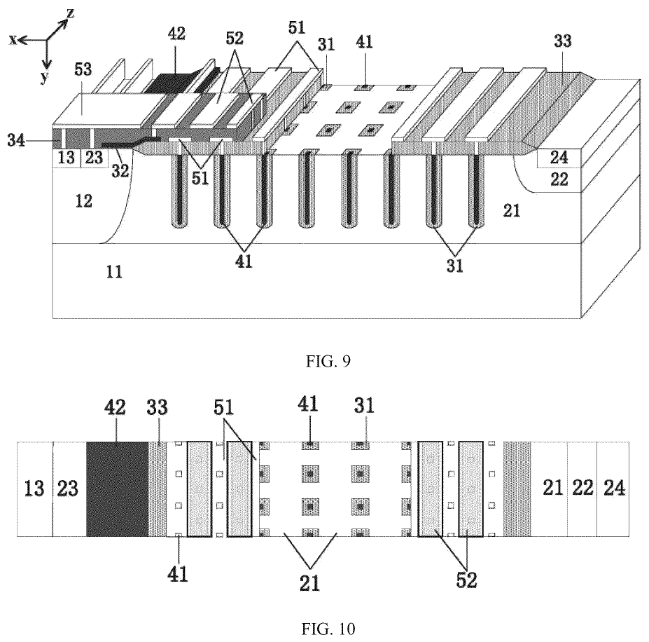

As shown in FIG. 9 and FIG. 10, FIG. 9 and FIG. 10 are schematic structural diagrams of a homogenization field device with low specific on-resistance based on multidimensional coupled voltage dividing mechanism in the embodiment 8. The difference between the embodiment 8 and the embodiment 1 lies in that the vertical floating field plates separated from the source electrode and the drain electrode at an equal interval and distributed in the entire second conductive type drift region 21 are connected to the first layer of metal strips 51 via holes to form the internal parallel equipotential ring array, and its working mechanism is substantially same with that of the embodiment 1.

### Embodiment 9

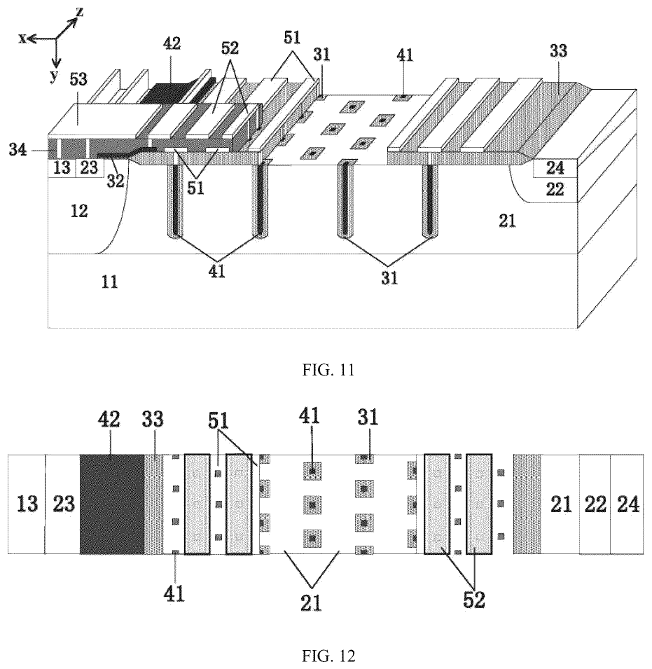

As shown in FIG. 11 and FIG. 12, FIG. 11 and FIG. 12 are schematic structural diagrams of a homogenization field device with low specific on-resistance based on multidimensional coupled voltage dividing mechanism in the embodiment 9. The difference between the embodiment 9 and the embodiment 1 lies in that the vertical floating field plates separated from the source electrode and the drain electrode at an equal interval and distributed in the entire second conductive type drift region 21 are connected to the first layer of metal strips 51 via the through holes to form the internal staggered equipotential ring array, and its working mechanism is substantially same with that of the embodiment 1.

### Embodiment 10

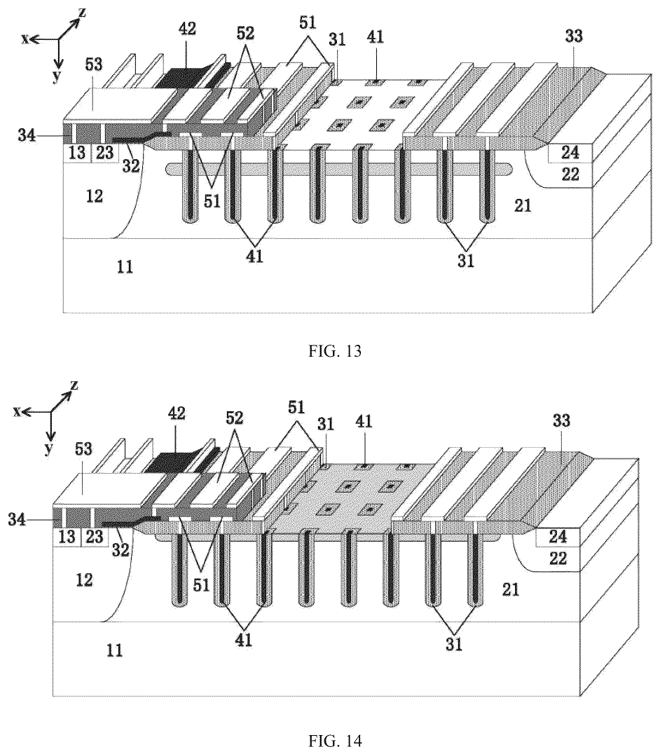

As shown in FIG. 13, FIG. 13 is a schematic structural diagram of a homogenization field device with low specific on-resistance based on multidimensional coupled voltage dividing mechanism in the embodiment 10. The difference between the embodiment 10 and the embodiment 1 lies in that the first conductive type buried layer is introduced into the second conductive type drift region 21, and its working mechanism is substantially same with that of the embodiment 1.

### Embodiment 11

As shown in FIG. 14, FIG. 14 is a schematic structural diagram of a homogenization field device with low specific on-resistance based on multidimensional coupled voltage dividing mechanism in the embodiment 11. The difference between the embodiment 11 and the embodiment 1 lies in that the first conductive type top layer is introduced onto the surface of the second conductive type drift region 21 and new self charge balance is developed by the first conductive type buried layer region, which fixes the surface electric field and leads to an almost constant breakdown voltage in a wide doping range, and its working mechanism is substantially same with that of the embodiment 1.

### Embodiment 12

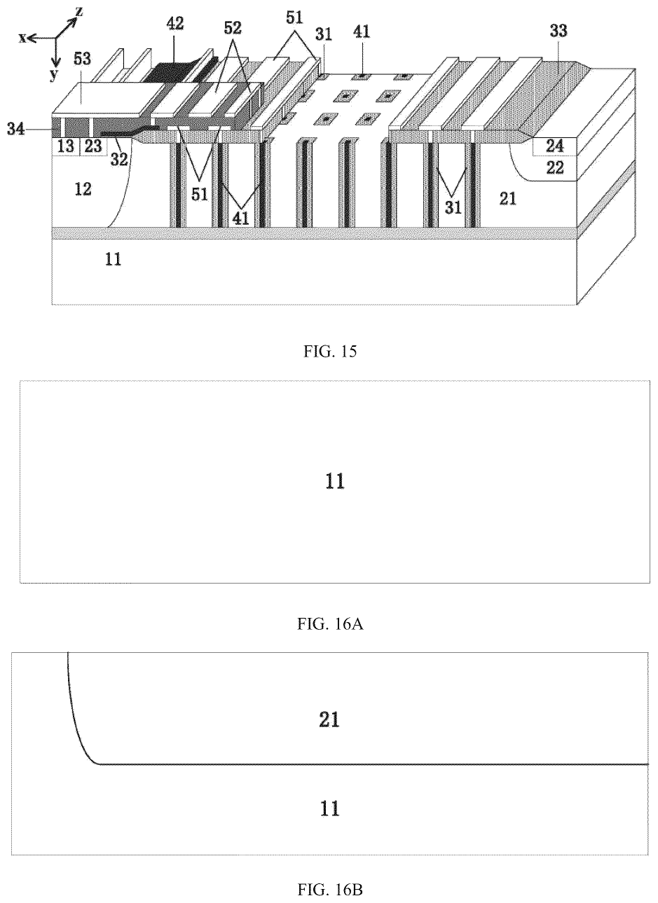

As shown in FIG. 15, FIG. 15 is a stereo schematic structural diagram of a homogenization field device with low specific on-resistance based on multidimensional coupled voltage dividing mechanism in an embodiment 12. The difference between the embodiment 12 and the structure in the embodiment 1 lies in that the device is an SOI device rather than a bulk silicon device, and its working mechanism is substantially same with the embodiment 1.

The above-mentioned embodiments merely exemplarily describe the mechanism and functions of the present invention and are not intended to limit the present invention. Any one skilled in the art can modify or vary the above-mentioned embodiments without departing the spirit and scope of the present invention. Therefore, all equivalent modifications or variations made by those skilled in the art with general knowledge without departing from the spirit and thought of technology disclosed by the present invention shall still be covered by the claims of the present invention.

What is claimed is:

1. A homogenization field device with a low specific on-resistance based on a multidimensional coupled voltage dividing mechanism, comprising:
a first conductive type semiconductor substrate, a first conductive type well region, a first conductive type source heavily doped region, a second conductive type drift region, a second conductive type well region, a second conductive type source heavily doped region, a second conductive type drain heavily doped region, a first dielectric oxide layer, a second dielectric oxide layer, a third dielectric oxide layer, a fourth dielectric oxide layer, a polycrystalline silicon electrode, a polycrystalline silicon electrode of a control gate, a first layer of metal strips, a second layer of metal strips, a source electrode metal, and a drain electrode metal;
wherein the second conductive type drift region is located above the first conductive type semiconductor substrate, the first conductive type well region is located on a left side of the second conductive type drift region, the second conductive type well region is located on a right side of the second conductive type drift region, the first conductive type source heavily doped region and the second conductive type source heavily doped region on a source side region are located in the first conductive type well region and both are heavily doped to reduce resistance, and the source electrode metal is located on upper surfaces of the first conductive type source heavily doped region and the second conductive type source heavily doped region; the second conductive type drain heavily doped region is located in the second conductive type well region, and the drain electrode metal is located on an upper surface of the second conductive type drain heavily doped region; the second dielectric oxide layer is located above the first conductive type well region, wherein a left end of the second dielectric oxide layer contacts the second conductive type source heavily doped region, and a right end of the second dielectric oxide layer contacts the second conductive type drift region; the third dielectric oxide layer is located on an upper surface of the second conductive type drift region located between the second dielectric oxide layer and the second conductive type drain heavily doped region, and the fourth dielectric oxide layer is located on a surface of the homogenization field device; the polycrystalline silicon electrode of the control gate covers an upper surface of the second dielectric oxide layer and partially extends to an upper surface of the third dielectric oxide layer; the first layer of metal strips are located on the upper surface of the third dielectric oxide layer and in the fourth dielectric oxide layer, the second layer of metal strips are located on an upper surface of the fourth dielectric oxide layer, and a heavy doping concentration is greater than 1E18 cm⁻³;
the first dielectric oxide layer and the polycrystalline silicon electrode form a vertical floating field plate, and the first dielectric oxide layer encircles the polycrystalline silicon electrode; vertical floating field plates are distributed in the entire second conductive type drift region to form a vertical floating field plate array; the vertical floating field plates distributed in the entire second conductive type drift region at equal distances from a source and a drain are connected to the first layer of metal strips through holes; a fixed capacitor formed between the equidistance first layer of metal strips distributed on the upper surface of the third dielectric oxide layer and in the fourth dielectric oxide layer and the equidistance second layer of metal strips distributed on the upper surface of the fourth dielectric oxide layer fixes the potential of the vertical floating field plate array distributed in the entire second conductive type drift region by capacitive coupling at a device off state, so that the second conductive type drift region is depleted continuously and a voltage is divided uniformly; and
the second layer of metal strips and the first layer of metal strips realize multidimensional coupled voltage division; a direction from the source to the drain is an x direction, a depth downward direction of the vertical floating field plate is a y direction, and a z direction is perpendicular to the x direction and the y direction.

2. The homogenization field device according to claim 1, wherein the second layer of metal strips are continuous vertical strips in the z direction that are repeatedly arranged along the x direction, or the second layer of metal strips are discrete vertical strips in the z direction that are repeatedly arranged along the x direction, or the second layer of metal strips are the continuous vertical strips in the z direction and the discrete vertical strips in the z direction that are alternately arranged along the x direction.

3. The homogenization field device according to claim 1, wherein the first layer of metal strips are made from a polycrystalline silicon material, the second layer of metal strips and the first layer of metal strips are connected via holes and are staggered in the x direction, or a plurality of layers of metal strips and the first layer of metal strips are connected via holes and are staggered in the x direction to realize multidimensional coupled voltage division.

4. The homogenization field device according to claim 1, wherein a drain vertical floating field plate is formed at the drain by using a process identical to the vertical floating field plate array in the second conductive type drift region, the drain vertical floating field plate penetrates through the second conductive type drain heavily doped region and the second conductive type well region, and a polycrystalline silicon electrode of the drain vertical floating field plate is connected to the drain electrode metal.

5. The homogenization field device according to claim 1, wherein the vertical floating field plates form an internal parallel equipotential ring array or an internal staggered equipotential ring array.

6. The homogenization field device according to claim 1, wherein a first conductive type buried layer is introduced into the second conductive type drift region.

7. The homogenization field device according to claim 1, wherein a first conductive type top layer is introduced onto a surface of the second conductive type drift region.

8. The homogenization field device according to claim 1, wherein a layer of dielectric layer is clamped between top layer silicon and the first conductive type semiconductor substrate.

9. A method for manufacturing the homogenization field device with the low specific on-resistance based on the multidimensional coupled voltage dividing mechanism according to claim 1, comprising the following steps:
S1: selecting the first conductive type semiconductor substrate;
S2: performing ion implantation of a second conductive type impurity and performing heating process promotion to form the second conductive type drift region;
S3: forming a trench by Photolithography and etching;
S4: forming the first dielectric oxide layer in the trench;
S5: depositing polycrystal silicon and etching the polycrystal silicon to a silicon plane to form the polycrystalline silicon electrode;
S6: performing ion implantation of a first conductive type impurity and high temperature diffusion process to form junction to form the first conductive type well region, and then performing ion implantation of the second conductive type impurity and high temperature diffusion process to form junction to form the second conductive type well region;
S7: forming the second dielectric oxide layer and then forming the third dielectric oxide layer;
S8: depositing the polycrystal silicon and etching the polycrystal silicon to form the polycrystalline silicon electrode of the control gate;
S9: performing ion implantation to form the first conductive type source heavily doped region, the second conductive type source heavily doped region and the second conductive type drain heavily doped region;
S10: etching the third dielectric oxide layer to form a contact hole, and then depositing and etching to form the first layer of metal strips, or depositing and etching to form a first layer of polycrystalline silicon strips;
S11: depositing to form the fourth dielectric oxide layer;
S12: depositing and etching to form the second layer of metal strips, the source electrode metal and the drain electrode metal.

10. The method according to claim 9, wherein the second conductive type drift region formed by implantation and knob pushing in S2 is obtained by an epitaxial method; and/or the first conductive type well region and the second conductive type well region obtained by implantation and high temperature diffusion process to form junction in S6 are formed by multiple implantations of different energies and activated.

11. The method according to claim 9, wherein in the homogenization field device, the second layer of metal strips are continuous vertical strips in the z direction that are repeatedly arranged along the x direction, or the second layer of metal strips are discrete vertical strips in the z direction that are repeatedly arranged along the x direction, or the second layer of metal strips are the continuous vertical strips in the z direction and the discrete vertical strips in the z direction that are alternately arranged along the x direction.

12. The method according to claim 9, wherein in the homogenization field device, the first layer of metal strips are made from a polycrystalline silicon material, the second layer of metal strips and the first layer of metal strips are connected via holes and are staggered in the x direction, or a plurality of layers of metal strips and the first layer of metal strips are connected via holes and are staggered in the x direction to realize multidimensional coupled voltage division.

13. The method according to claim 9, wherein in the homogenization field device, a drain vertical floating field plate is formed at the drain by using a process identical to the vertical floating field plate array in the second conductive type drift region, the drain vertical floating field plate penetrates through the second conductive type drain heavily doped region and the second conductive type well region, and a polycrystalline silicon electrode of the drain vertical floating field plate is connected to the drain electrode metal.

14. The method according to claim 9, wherein in the homogenization field device, the vertical floating field plates form an internal parallel equipotential ring array or an internal staggered equipotential ring array.

15. The method according to claim 9, wherein in the homogenization field device, a first conductive type buried layer is introduced into the second conductive type drift region.

16. The method according to claim 9, wherein in the homogenization field device, a first conductive type top layer is introduced onto a surface of the second conductive type drift region.

17. The method according to claim 9, wherein in the homogenization field device, a layer of dielectric layer is clamped between top layer silicon and the first conductive type semiconductor substrate.
